(19) United States
(12) Patent Application Publication
(10) Pub. No.: US 2008/0113273 A1
(43) Pub. Date: May 15, 2008

(54) Wafer scale lens module and manufacturing method thereof

(75) Inventors: Young Su Jin, Seoul (KR); Hye Ran Oh, Gyunggi-do (KR); In Cheol Chang, Gyunggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/979,743

(22) Filed: Nov. 7, 2007

(30) Foreign Application Priority Data
Nov. 14, 2006 (KR) 10-2006-0112088

(51) Int. Cl. G03F 1/00; G03C 1/72

(52) U.S. Cl. 430/4; 430/270.1

(57) ABSTRACT

There are provided a wafer scale lens module and a manufacturing method thereof. A wafer scale lens module including: at least one lens including a lens substrate and a lens element deposited on at least one surface of the lens substrate, wherein a stop is integrally formed on at least one surface of the lens to adjust light amount. The stop may be a photo resist layer. The wafer scale lens module is lighter in weight and smaller in size and has a stop formed of a photo resist which is excellently bonded to a UV curing polymer, thereby precluding a need for forming an additional bonding film. The stop can be fabricated only through an exposure process due to characteristics of the photo resist, thereby saving manufacturing costs and time.

### CROSS-REFERENCE TO RELATED APPLICATIONS

This application claims the priority of Korean Patent Application No. 2006-112088 filed on Nov. 14, 2006, in the Korean Intellectual Property Office, the disclosure of which is incorporated herein by reference.

### BACKGROUND OF THE INVENTION

1. Field of the Invention

The present invention relates to a wafer scale lens module and a manufacturing method thereof, and more particularly, to a wafer scale lens module having a stop formed integrally on at least one surface of a lens to adjust light amount, and a manufacturing method thereof.

2. Description of the Related Art

Recently, a smaller image sensor has led to miniaturization of electronic devices adopting the image sensor. This smaller trend has hit mobile phones which are extensively popular due to portability and convenience, resulting in explosive growth of the mobile phone camera module market. Moreover, buoyed by the spectacular growth of the mobile phone market, a demand for an inexpensive and high-performing camera module has been on the rise.

FIG. 1 is a view illustrating a lens module provided with a general stop.

The lens module is generally for use in a subminiature camera and configured such that a first lens 1, a second lens 2 and a third lens 3 are arranged sequentially from an object side.

Also, a filter 5 and an image sensor 6 are disposed next to the third lens 3. The filter 5 typically adopts an infrared ray (IR) filter.

In the lens module described above, an aperture 4 is disposed in front of the first lens 1 as an additional instrument to determine an incident light amount and resolution.

But the aperture 4 disposed outside the lenses as in the conventional subminiature camera lens module of FIG. 1, hinders reduction in size and weight of the lens module.

Especially, these days, to manufacture a smaller-sized and lower-cost lens module, a wafer scale lens is produced by a UV replica process, unlike a conventional technology of fabricating a single lens by injection for assembling. Accordingly, the aperture needs to be formed inside the lens module without being disposed as an additional instrument.

### SUMMARY OF THE INVENTION

An aspect of the present invention provides a smaller-sized and lighter-weight wafer scale lens module in which a stop is formed on one surface of a lens, in place of an aperture disposed outside lenses, and a manufacturing method thereof.

According to an aspect of the present invention, there is provided a wafer scale lens module including: at least one lens including a lens substrate and a lens element deposited on at least one surface of the lens substrate, wherein a stop is integrally formed on at least one surface of the lens to adjust light amount.

The stop may be a photo resist layer.

The photo resist layer may be formed of a black photo resist.

The photo resist layer may absorb at least 95% of light in a visible light region.

The stop may be formed on the lens substrate having the lens element deposited thereon.

The lens may have stops formed integrally on both surfaces thereof, respectively, to adjust the light amount.

The lens having the stop thereon may be a plurality of lenses.

According to another aspect of the present invention, there is provided a method of manufacturing a wafer scale lens, the method including: depositing a photo resist on at least one surface of a lens substrate; forming a stop for adjusting light amount on the lens substrate by exposing and developing the lens substrate having the photo resist deposited thereon; injecting a lens material onto the lens substrate having the stop formed thereon; and forming a lens element using a molding.

The forming a stop on the lens substrate may include irradiating light onto the lens substrate having the photo resist deposited thereon to remove only a portion of the photo resist corresponding to a light exit opening.

The photo resist may be a black photo resist.

The photo resist may absorb at least 95% of light in a visible light region.

The lens substrate may have stops formed on both surfaces thereof, respectively.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view illustrating arrangement of an optical system with a conventional aperture;

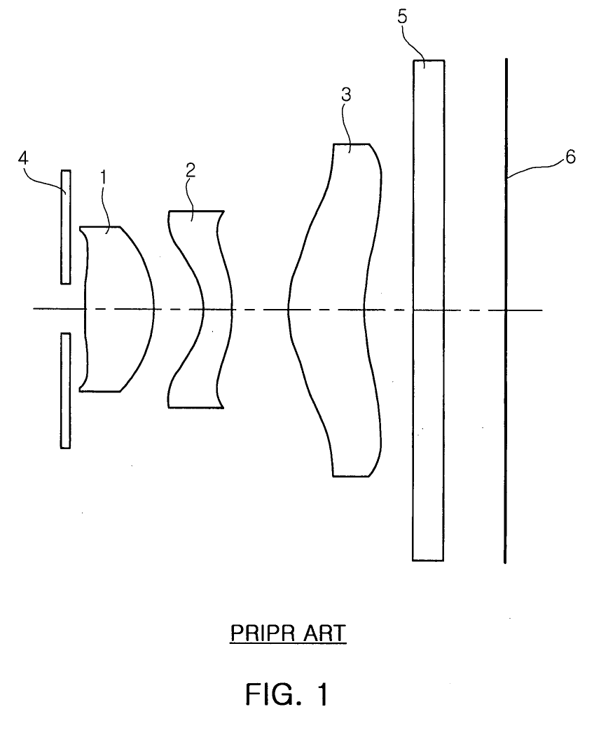

FIG. 2 is a view illustrating arrangement of a wafer scale lens module according to an exemplary embodiment of the invention;

FIG. 3 is a configuration view illustrating a wafer scale lens according to an exemplary embodiment of the invention;

FIG. 4 is a configuration view illustrating a wafer scale lens according to another exemplary embodiment of the invention;

FIG. 5 is a view illustrating a method of manufacturing a wafer scale lens according to an exemplary embodiment of the invention;

FIG. 6 is a view illustrating a wafer scale lens having stops formed on both surfaces of a lens substrate shown in FIG. 6.

### DETAILED DESCRIPTION OF THE PREFERRED EMBODIMENT

Exemplary embodiments of the present invention will now be described in detail with reference to the accompanying drawings.

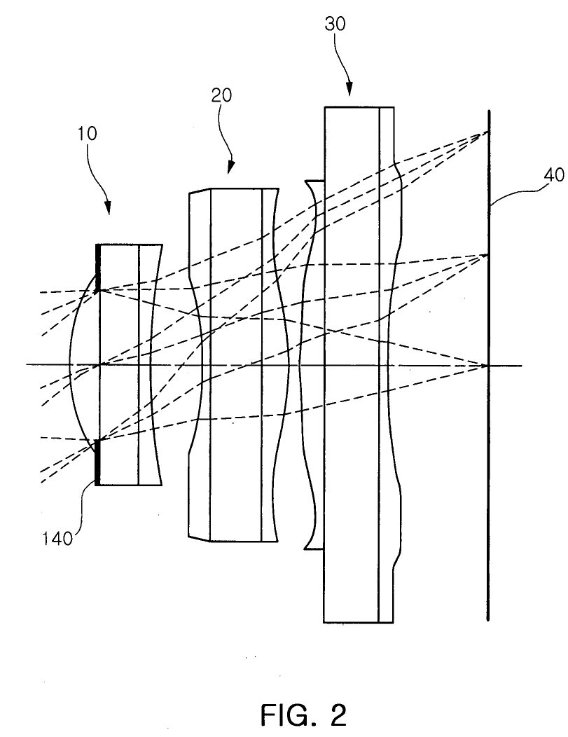

FIG. 2 is a view illustrating arrangement of a wafer scale lens module according to an exemplary embodiment of the invention.

The wafer scale module of the present embodiment includes, sequentially from an object side, a first lens 10, a second lens 20, and a third lens 30, and an image sensor 40 disposed next to the third lens 30.

The lenses 10, 20 and 30 are fabricated by a replica method in which a transparent optical material such as polymer is deposited on a top of a transparent lens substrate made of glass to form a lens element. However, the present embodiment is not limited thereto and the lenses 10, 20 and 30 may be manufactured by various methods.

Here, as shown in FIG. 2, a stop 140 is formed integral with the first lens 10. The stop 140 serves as an aperture for adjusting an amount of light incident from the object side.

In the present embodiment, the stop 140 is formed integral with the first lens 10 but alternatively, may be formed integral with the second lens 20 or third lens 30 to adjust light amount.

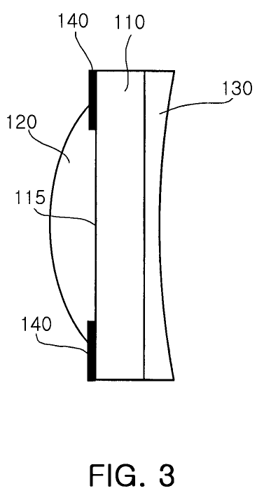

FIG. 3 is a configuration view illustrating a wafer scale lens, i.e., the first lens in FIG. 2 according to an exemplary embodiment of the invention.

The wafer scale lens includes a lens substrate 110, a first lens element 120 deposited on one surface of the lens substrate 110 and a second lens element 130 deposited on another surface of the lens substrate 110. Also, a stop 140 is integrally formed on the surface of the lens substrate 110 having the first lens element 120 deposited thereon.

Here, the stop 140 is formed on the surface of the lens substrate 110 excluding a portion corresponding to a light exit opening 115. The first lens element 120 formed of polymer is deposited on the surface of the lens substrate 110 having the stop 140 formed thereon. Therefore, the first lens element 120 has edges in contact with a top surface of the stop 140 and a central portion in contact with the surface of the lens substrate 110 corresponding to the light exit opening 115.

Also, the second lens element 130 is in entire contact with another surface of the lens substrate 110 which opposes the surface of the lens substrate 110 having the first lens element 120 deposited thereon.

Meanwhile, unlike FIG. 3, the wafer scale lens of the present embodiment may have only the first lens element 120 deposited on the surface of the lens substrate 110, without the second lens element 130 deposited on the lens substrate 110.

The stop 140 may be formed of a metal film using e.g., aluminum (Al) or chrome (Cr) but particularly may be integrally formed on the surface of the lens substrate 110 utilizing a photo resist composition such as a black photo resist.

That is, the stop 140 of the present embodiment is formed of a photo resist resin layer.

Here, the photo resist is one of a polymer and a polymer composition which are changed in a molecular structure by optical function and subsequently in physical properties.

The photo resist resin described above is mainly composed of a polymer, a solvent, and a sensitizer, and classified into a positive photo resist and a negative photo resist according to type of development. For the positive photo resist, an exposed portion disappears after development and for the negative photo resist, an exposed portion remains after development.

As described above, the stop 140, when formed as the photo resist resin layer on the lens substrate 110 according to the present embodiment, can be manufactured in a simpler process than when a metal film using, e.g., aluminum (Al) or chrome (Cr) is adopted. Also, the stop 140 is excellently bonded to a UV curing polymer used for the first lens element 120.

Specifically, the stop 140, when formed as the metal film using, e.g., aluminum (Al) or chrome (Cr), is less bonded to the UV curing polymer due to high hydrophobic properties of the metal film, thus requiring an additional bonding film to be formed on the metal film.

On the other hand, the stop 140 formed as the photo resist layer is superbly bonded to the UV curing polymer due to high hydrophilic properties of the photo resist resin, thus precluding a need for forming an additional bonding film on the photo resist layer.

Moreover, the stop 140, when formed as the metal film entails sequential processes such as exposure, and deposition and removal of the metal film. However, the stop 140, when formed as the photo resist layer can be fabricated only through an exposure process due to characteristics of the photo resist resin, thereby saving manufacturing costs and time.

In the meantime, the metal film using e.g., aluminum Al or chrome Cr has high reflectivity so that some portion of light passing through the stop 140 re-reflects an unnecessary portion of light reflected by the lens substrate 110 or the lens elements, consequently degrading definition. On the other hand, the photo resist layer has high light absorption in a visible light region, thereby preventing definition from being degraded by total internal reflection described above.

Here, the photo resist resin layer defining the stop 140 may absorb at least 95% of light in a visible light region.

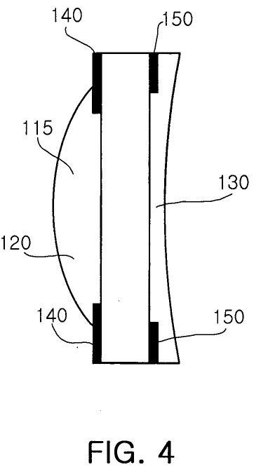

FIG. 4 illustrates a wafer scale lens according to another exemplary embodiment of the invention.

FIG. 4 is a configuration view illustrating the wafer scale lens according to another exemplary embodiment of the invention.

The wafer scale lens of the present embodiment is identical in construction to the wafer scale lens of the aforesaid embodiment except that stops 140 and 150 are integrally formed on both surfaces of a lens substrate, respectively, to adjust light amount. Therefore like components are designated with like numerals and will not be explained in further detail.

Referring to FIG. 4, the wafer scale lens includes the lens substrate 110, a first lens element 120 deposited on one surface of the lens substrate 10 and a second lens element 130 deposited on another surface of the lens substrate 110.

A first stop 140 is formed integral on the surface of the lens substrate 110 having the first lens element 120 deposited thereon and a second stop 150 is formed on the surface of the lens substrate 110 having the second lens element 130 deposited thereon.

Here, the first stop 140 is formed on the surface of the lens substrate 110 excluding a portion corresponding to a light exit opening 115, and the first lens element 120 formed of a polymer material is deposited on the surface of the lens substrate 110 having the first stop 140 formed thereon. Therefore, the first lens element 120 has edges in contact with a top surface of the first stop 140 and a central portion in contact with the surface of the lens substrate 110 corresponding to the light exit opening 115.

Furthermore, the second stop 150 is formed on the another surface of the lens substrate 110, and the second lens element 130 is deposited on the lens substrate 110 so as to have edges in contact with a top surface of the second stop 150.

As described above, the stops 140 and 150 formed as photo resist resin layers on the both surfaces of the lens substrate 110 serve as a baffle, thereby ensuring a view angle.

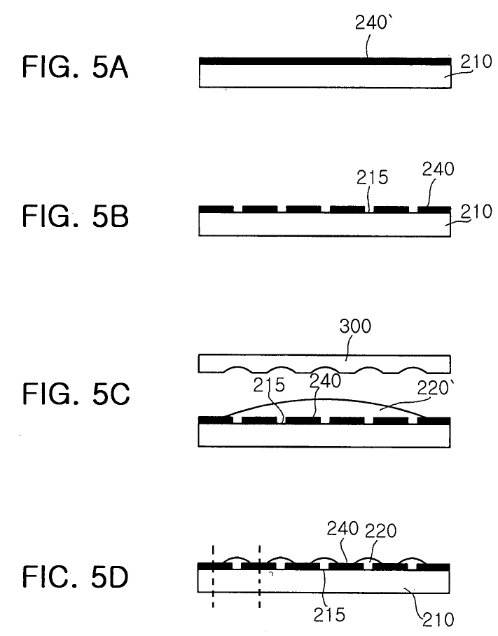

Hereinafter, a method of manufacturing a wafer scale lens according to the present embodiment will be described with reference to FIG. 5.

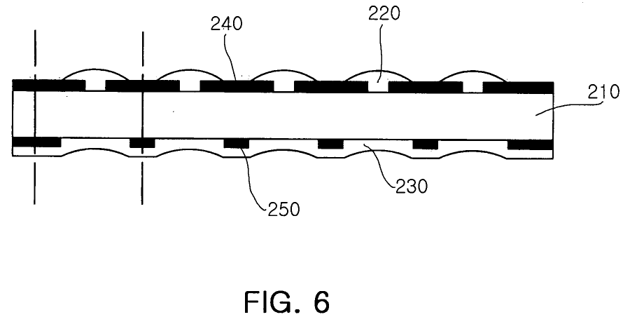

FIG. 5 is a view illustrating the method of manufacturing a wafer scale lens according to an exemplary embodiment of the invention and FIG. 6 is a view illustrating a wafer scale lens having stops 240 formed on both surfaces of a lens substrate 210, respectively.

First, as shown in FIG. 5A, a photo resist resin 240′ such as a black photo resist is deposited on the lens substrate 210. The photo resist resin 240′ may absorb at least 95% of light in a visible light region.

Thereafter, as shown in FIG. 5B, the lens substrate 210 having the photo resist resin 240′ deposited thereon is exposed and developed to form a stop 240 for adjusting light amount on the lens substrate 210. Specifically, a mask (not shown) with a uniform pattern thereon is placed over the lens substrate 210 having the photo resist resin 240′ deposited thereon and then light is irradiated to remove only a portion of the photo resist resin 240′ corresponding to a light exit opening 215.

According to the present embodiment, only the negative photo resist resin 240′ is applied, thus leaving an exposed portion after development as the stop 240. However, the present embodiment is not limited thereto and a positive photo resist resin may be utilized to form the stop.

Subsequently, as shown in FIG. 5C, a lens material 220′ formed of a transparent optical material such as a UV curing polymer is injected onto the lens substrate 210 having the stop 240 formed thereon, and then a molding 300 with the shape of a plurality of lens elements 220 formed thereon is compressed onto the lens substrate 210 having the lens material 220′ injected thereonto.

Finally, the lens material 220′ is cured by irradiating ultraviolet rays UV and then the molding 300 is removed to obtain a plurality of wafer scale lenses as shown in FIG. 5D. The wafer scale lenses are cut along dotted lines into separate wafer scale lenses.

The method of manufacturing a wafer scale lens using the photo resist resin 240′ according to the present embodiment allows the stop 240 to be formed on the lens substrate in a simple process.

That is, the stop 240, when formed as a metal film using e.g., aluminum (Al) or chrome (Cr), entails sequential processes such as exposure, and deposition and removal of the metal film. On the other hand, the stop 240, when formed of the photo resist resin 240′ can be fabricated only through an exposure process due to characteristics of the photo resist resin 240′, thereby reducing manufacturing costs and time.

The photo resist resin 240′ is excellently bonded to the UV curing polymer due to hydrophilic properties thereof, thus precluding a need for forming an additional bonding film on a layer of the photo resist 240′.

Meanwhile, as shown in FIG. 6, stops 240 and 250 may be formed on both surfaces of the lens substrate 210, respectively to ensure a view angle according to the manufacturing method as described above.

As set forth above, according to exemplary embodiments of the invention, in a wafer scale lens module and a manufacturing method thereof, a stop is formed on at least one surface of a lens in place of adopting an aperture as an additional instrument, to adjust light amount. This produces a lighter and smaller lens module.

Also, the stop is formed of a photo resist resin superbly bondable with a UV curing polymer, thus obviating a need for forming an additional bonding film. Moreover, the stop can be formed only through an exposure process due to characteristics of the photo resist resin, thereby reducing manufacturing costs and time.

In addition, the photo resist resin exhibits high light absorption in a visible light region, thus preventing definition from being degraded by total internal reflection occurring in the lens module.

While the present invention has been shown and described in connection with the exemplary embodiments, it will be apparent to those skilled in the art that modifications and variations can be made without departing from the spirit and scope of the invention as defined by the appended claims.

What is claimed is:

1. A wafer scale lens module comprising:
at least one lens including a lens substrate and a lens element deposited on at least one surface of the lens substrate,
wherein a stop is integrally formed on at least one surface of the lens to adjust light amount.

2. The wafer scale lens module of claim 1, wherein the stop is a photo resist layer.

3. The wafer scale lens module of claim 2, wherein the stop is a negative photo resist layer.

4. The wafer scale lens module of claim 2, wherein the stop is a positive photo resist layer.

5. The wafer scale lens module of claim 2, wherein the photo resist layer is formed of a black photo resist.

6. The wafer scale lens module of claim 2, wherein the photo resist layer absorbs at least 95% of light in a visible light region.

7. The wafer scale lens module of claim 1, wherein the stop is formed on the lens substrate having the lens element deposited thereon.

8. The wafer scale lens module of claim 1, wherein the lens has stops formed integrally on both surfaces thereof, respectively, to adjust the light amount.

9. The wafer scale lens module of claim 1, wherein the lens having the stop thereon comprises a plurality of lenses.

10. A method of manufacturing a wafer scale lens, the method comprising:
depositing a photo resist on at least one surface of a lens substrate;
forming a stop for adjusting light amount on the lens substrate by exposing and developing the lens substrate having the photo resist deposited thereon;
injecting a lens material onto the lens substrate having the stop formed thereon; and
forming a lens element using a molding.

11. The method of claim 10, wherein the forming a stop on the lens substrate comprises irradiating light onto the lens substrate having the photo resist deposited thereon to remove only a portion of the photo resist corresponding to a light exit opening.

12. The method of claim 10, wherein the photo resist is a negative photo resist.

13. The method of claim 10, wherein the photo resist is a positive photo resist.

14. The method of claim 10, wherein the photo resist is a black photo resist.

15. The method of claim 10, wherein the photo resist absorbs at least 95% of light in a visible light region.

16. The method of claim 10, wherein the lens substrate has stops formed on both surfaces thereof, respectively.
